(19) United States
(12) Patent Application Publication
(10) Pub. No.: US 2011/0217848 A1
(43) Pub. Date: Sep. 8, 2011

(54) PHOTORESIST REMOVING PROCESSOR AND METHODS

(76) Inventors: Eric J. Bergman, Kalispell, MT (US); Jerry Dustin Leonhard, Kalispell, MT (US); Bryan Puch, Kalispell, MT (US); Jason Rye, Kalispell, MT (US)

(21) Appl. No.: 12/717,079

(22) Filed: Mar. 3, 2010

(51) Int. Cl. H01L 21/306

(52) U.S. Cl. 438/746; 156/345.21; 257/E21.219

(57) ABSTRACT

A processing chamber successfully removes hardened photoresist via direct infrared radiation onto the wafer, in the presence of an acid such as sulfuric acid, optionally along with an oxidizer such as hydrogen peroxide. The processing chamber includes a fixture for holding and optionally rotating the wafer. An infrared irradiating assembly has infrared lamps outside of the processing chamber positioned to radiate infrared light into the processing chamber. The infrared lamps may be arranged to irradiate substantially the entire surface of a wafer on the rotor. A cooling assembly can be associated with the infrared radiating assembly to provide a quick cool down and avoid over-processing. Photoresist is removed using small amounts of chemical solutions.

### BACKGROUND

Semiconductor wafer patterns are typically created by applying a photoresist to the wafer surface. Exposing a pattern on the wafer alters the chemical bonding of the photoresist, which allows certain regions to be removed using a developer while other regions become relatively inert to the developer. Photoresist may be either positive or negative, which denotes whether the light-exposed region or the non-light exposed region is removed in the developer. In either case, a pattern is created on the wafer which is used to mask the covered regions. The masking effect will protect the underlying layer from the effects of various etchants and from ion implants. Following such processing, the photoresist must then be removed.

Historically, photoresist has been removed by plasma ashing in an oxygen, ozone, or nitrous oxide containing environment, by oxidation in sulfuric acid or sulfuric acid and hydrogen peroxide mixtures, or by removal in ozone/water solutions. Photoresist dissolution in organic solvents is also used, though this is typically reserved for semiconductor wafers which have metal films or patterns present which might be attacked by strong oxidizing environments.

Various wet process chemicals have been used to remove photoresist. However, in many cases the prior processing of the wafer may have hardened or cross-linked the photoresist to an extent that the liquid chemicals are no longer effective in removing the photoresist. Hardening of the photoresist may be due to excessive plasma exposure during an etch process. Photoresist hardening is also very common when ion implantation occurs, for example, at a dosage above 1E15 atoms/cm.sup.2. Plasma ashing and dry ozone ashing are very effective at removing hardened photoresist. However, these processes can cause degradation of device performance due to plasma damage, the potential for hot-electron injection, mobile ion migration and surface attack. See U.S. Patent Publication No. 2007/0227556A1, incorporated herein by reference. Consequently, there is a need for new techniques for removing hardened photoresist, without detrimental effects to the semiconductor devices being manufactured.

### SUMMARY

A new processing chamber successfully removes hardened photoresist. By using direct IR radiation onto the wafer, in the presence of an acid such as sulfuric acid, optionally together with an oxidizer such as hydrogen peroxide, photoresist is quickly and effectively removed. In one aspect, the new processing chamber may include a rotor for holding and rotating the wafer. An infrared irradiating assembly having infrared lamps outside of the processing chamber can be positioned to radiate infrared light into the processing chamber. The infrared lamps may be arranged to irradiate substantially the entire surface of a wafer on the rotor. A cooling assembly can be associated with the infrared radiating assembly to provide a quick cool down and avoid over-processing.

In a new process, very small volumes of acid such as sulfuric acid, optionally with an oxidizer such as hydrogen peroxide, are applied onto a photoresist layer on a wafer. The wafer temperature is rapidly increased via radiant heating. The wafer is then cooled. The chemical reaction together with the radiant energy and/or heating removes the photoresist, while chemical consumption is minimized.

Other and further aspects and advantages will become apparent from the following detailed description and drawings. This description and drawings are provided as an example of various ways that the new processing chamber may be made, and are not intended to describe the limits of the invention. The invention resides as well in sub-combinations and sub-systems of the processor described.

### BRIEF DESCRIPTION OF THE DRAWINGS

In the drawings, the same number indicates the same element in each of the views.

FIG. 1 is a front perspective view of a processor for removing photoresist.

FIG. 2 is a section view of the processor shown in FIG. 1.

FIG. 3 is a top view of the processor shown in FIG. 1.

FIG. 4 is a rear perspective view of the processor shown in FIG. 1.

FIG. 5 is a section view of an alternative design.

FIG. 6 is a bottom view, looking up, of the heater housing shown in FIG. 1.

FIG. 7 is a bottom view, looking up, of lamp housing shown in FIG. 1.

FIG. 8 is a perspective view of the infrared radiating housing shown in FIG. 6 with the cover removed.

### DETAILED DESCRIPTION OF THE DRAWINGS

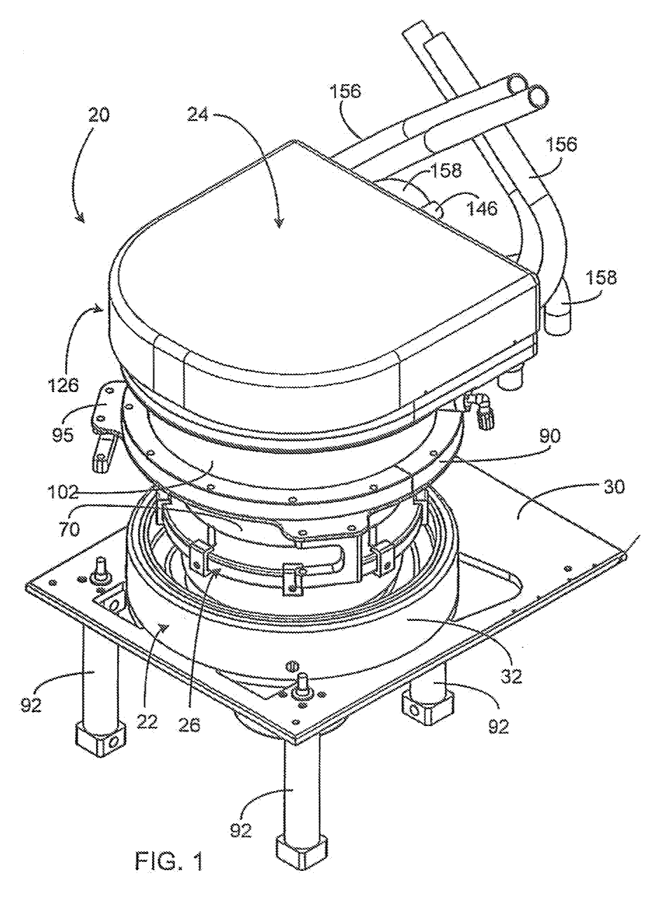

Turning now in detail to the drawings, as shown in FIG. 1, a processor 20 may include a first or lower chamber assembly 22 and a second or upper chamber assembly 24. In the design shown in FIG. 1, the lower chamber assembly 22 includes a bowl 32 supported on a base plate 30. A rotor assembly 26 adapted to hold and rotate a wafer 70, such as a silicon wafer, is contained within the lower chamber assembly 22. Alternatively, a fixed or non-rotating wafer holder may be used.

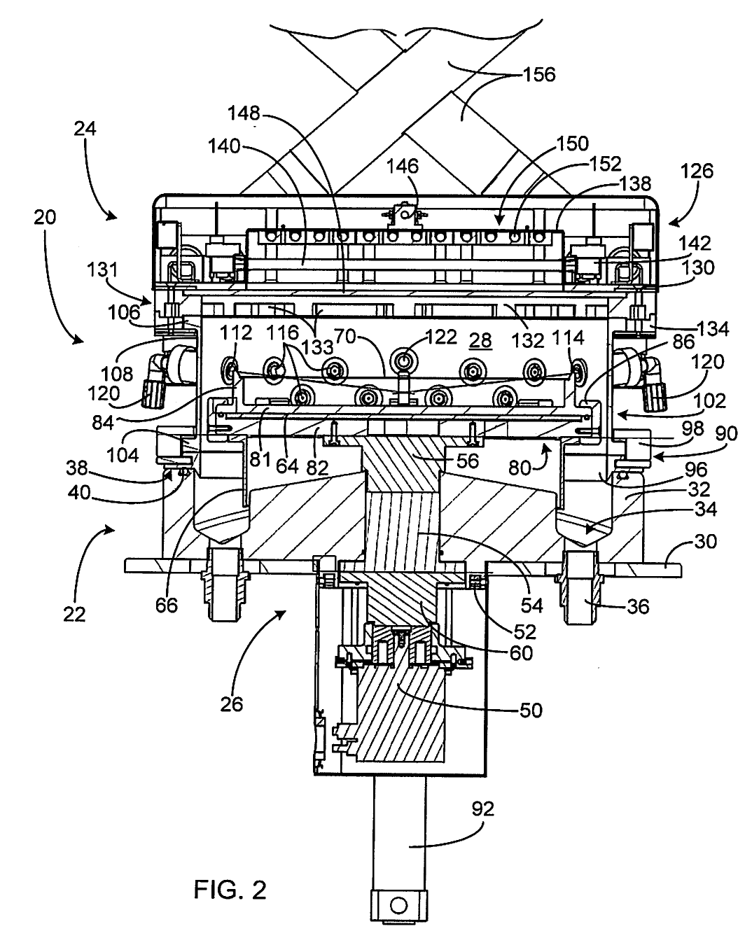

As shown in FIG. 2, the bowl 32 may include a fluid collection trough 34 having a drain fitting 36, for collection and removing fluid. A seal element 40, such as an o-ring, is provided on a top surface 38 of the bowl 32. The rotor assembly 26 includes a motor 50 that rotates a plate assembly 80 holding the wafer 70. Shield plate 64 is sandwiched in between top plate 81 and rotor plate 82, attached to rotor hub 56. Plate clip 86 holds the components of plate assembly 80 together. Fingers 84 extend perpendicularly from plate assembly 80, and are positioned around the periphery of rotor plate 82. Wafer 70 is restable on fingers 84 distal from, and substatually parrell to rotor plate 82. In the specific design shown in FIG. 2, the rotor assembly 26 also includes a rotor hub 56 connected to the upper and lower shaft, 54 and 60, respectively. The drive shaft spins freely while the motor 50 remains fixed in place. The motor 50 may be supported on a motor mounting plate 52 attached to the base plate 30, to rotatably support the rotor assembly 26 in the lower chamber assembly 22.

Fingers 84 or similar devices on the rotor assembly are attached to the plate assembly 80 to support and hold the wafer 70 at the edges. Attached to the rotor assembly 26 is a rotor curtain 66 which prevents liquid from reaching the upper drive shaft 54, lower drive shaft 60, and motor 50. The rotor assembly 26 is representative of one of various designs that may be used.

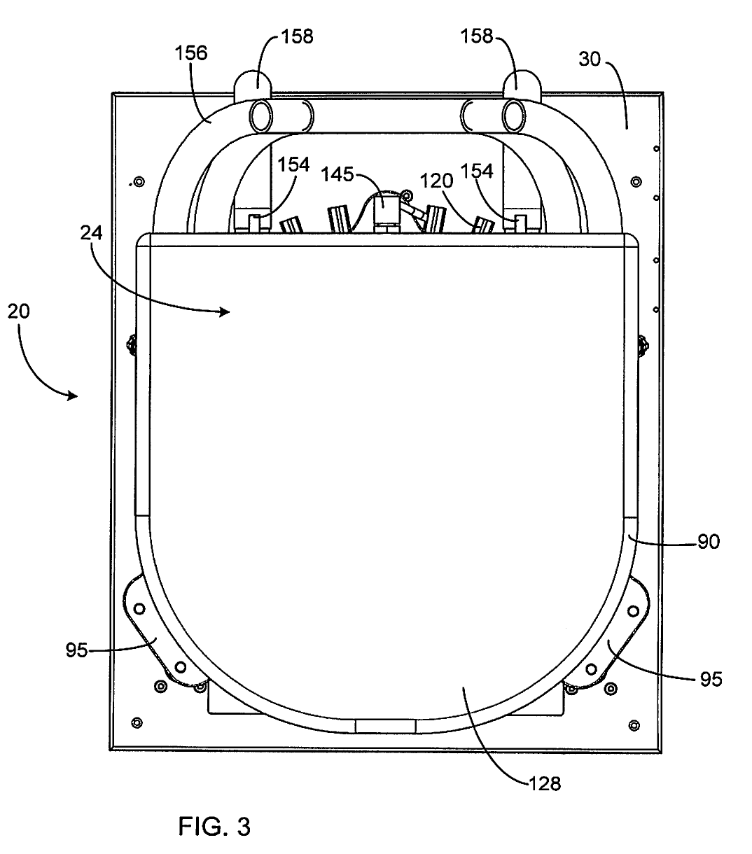

Referring still to FIG. 2, the upper chamber assembly 24 may include an annular upper chamber body 102 having a lower lip 104 and an upper lip 106. The body 102 can be attached to a lift ring 90 via a lower retainer ring 98. Referring momentarily to FIGS. 1, 2 and 3, lifting actuators 92 may be attached to ring tabs 95 on the lift ring 90. Lifting movement of the actuators accordingly lifts the entire upper chamber assembly 24 up and off of the lower chamber assembly 22. The lift ring 90 may therefore be made of corrosion resistant steel, or similar material. A bowl ring 96 may be provided over the lift ring 90, to shield the lift ring 90 from corrosive process fluids used within the processor 20. As shown in FIG. 2, with the processor 20 in the closed or process position, the bottom surface of the bowl ring 96 engages the seal element 40, to seal the upper chamber assembly 24 to the lower chamber assembly 22.

In the design shown, the lifting actuators used include a lift actuator 92 supported on the base plate 30 and having a shaft extending up and attached to a ring tab 95. FIG. 1 shows use of three lift actuators, although more or less may be used.

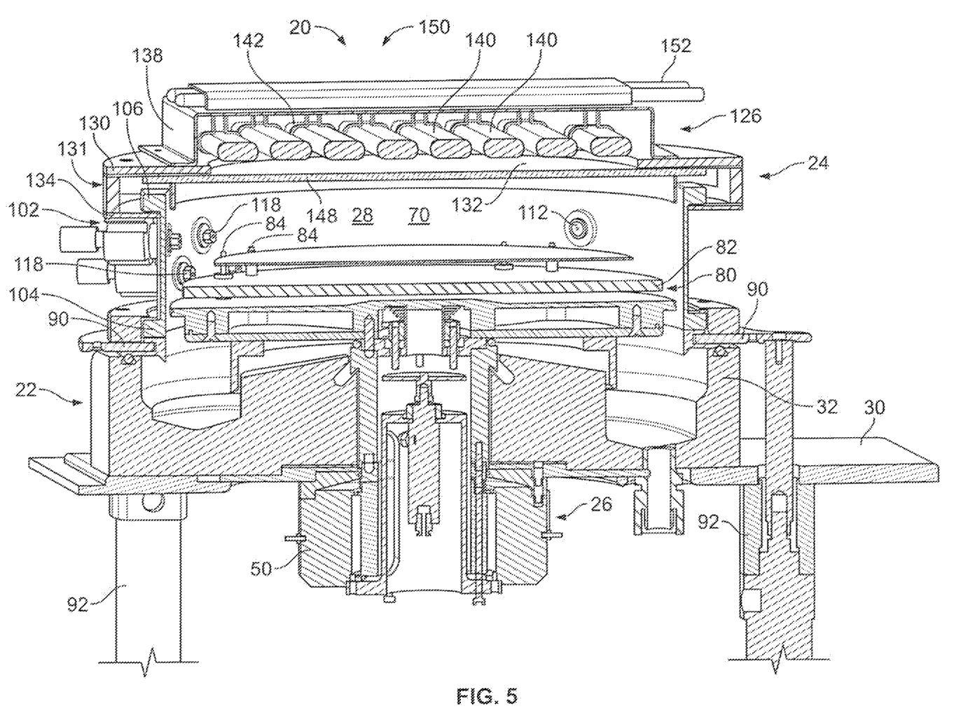

FIG. 5 shows an alternative processor having the same elements as the design shown in FIG. 2, but with different specific components selected. For example, as shown in FIG. 5, a different motor 50, bowl 32, rotor assembly 26, and other components are used.

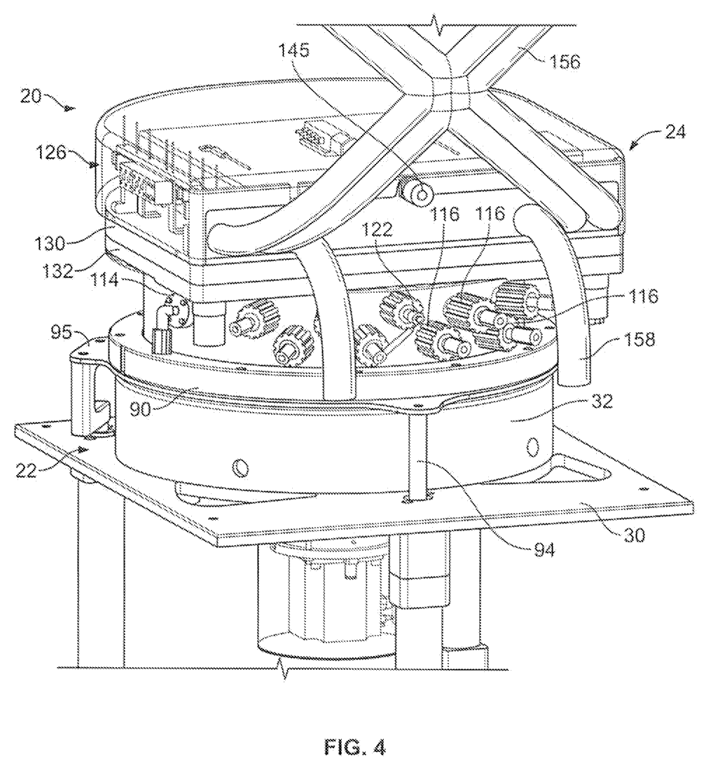

As shown in FIGS. 2 and 5, a processing chamber 28 is formed between the lower and upper chamber assemblies 22 and 24, when the processor 20 is in the closed or process position. Fluid outlets or nozzles provide process fluids into the chamber 28. Various nozzle numbers, types and positions may be used. FIGS. 2 and 5 show nozzles attached to the cylindrical sidewall 108 of the upper chamber body 102. Supply lines (not shown) deliver process fluids to the nozzles; various types of nozzles may be employed, including atomizing and spray nozzles. To perform the processes described below, the processor 20 is equipped with at least a sulfuric acid atomized nozzle 112 and a hydrogen peroxide atomized nozzle 114. The processor 20 generally also includes upper and lower de-ionized water nozzles 116. In the exemplary embodiment water nozzles 116 are paired in an upper and lower configuration, relative to the wafer 70. Typically two or more of these nozzles are used. FIG. 4 shows the back end of the nozzles and fluid fittings. Referring back to FIGS. 2, one or more chamber temperature sensors 122, such as a thermocouple or proxy sensor, may be provided in the chamber 28 to approximate the temperature of the wafer during processing.

As shown in FIG. 2, a head plate 130 is secured onto the upper chamber body 102 via an upper retainer plate 134. An exhaust plate 132 is held tight to the head plate 130, so as to secure an infrared transparent window 148 therebetween. The head plate 130 and the exhaust plate 132 each have a central through opening generally matching and generally centered on the plate assembly 80. The infrared transparent window 148 spans the opening and may be sealed to both the head plate 130 and the exhaust plate 132. The infrared transparent window 148 is positioned to permit light and/or IR energy to pass through the window and be absorbed by a wafer 70 positioned on the plate assembly 80. The exhaust plate 132 embodies at least one exhaust port 133. Exhaust ports 133 permit evacuation of the processing chamber 28.

FIGS. 2, 5, 6 and 8 show a radiation or infrared (IR) assembly 126 that may also be supported on the head plate 130 of the upper chamber assembly 24. As shown in FIG. 2, IR lamps 140 are provided in an array over the infrared transparent window 148. The lamps 140 may be suspended within a lamp housing 138 on holders or brackets 142. As shown in FIG. 8, one or more housing temperature sensors 144, such as thermocouples, may be attached to the lamp housing. Electrical power cables 156 provide power to the lamps 140.

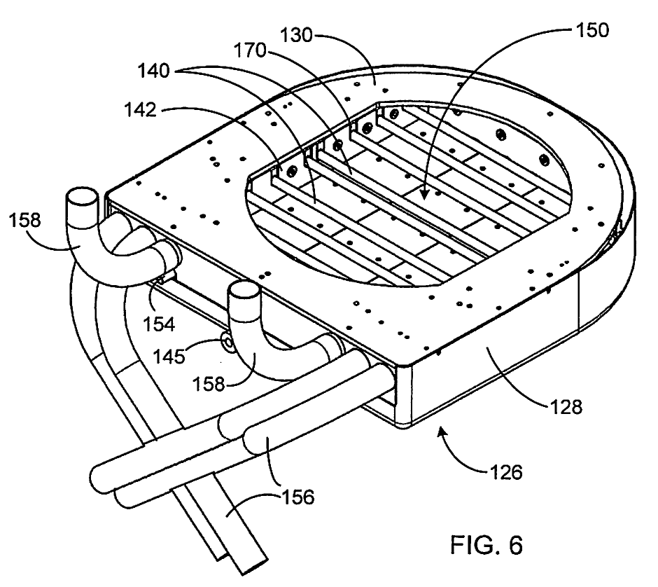

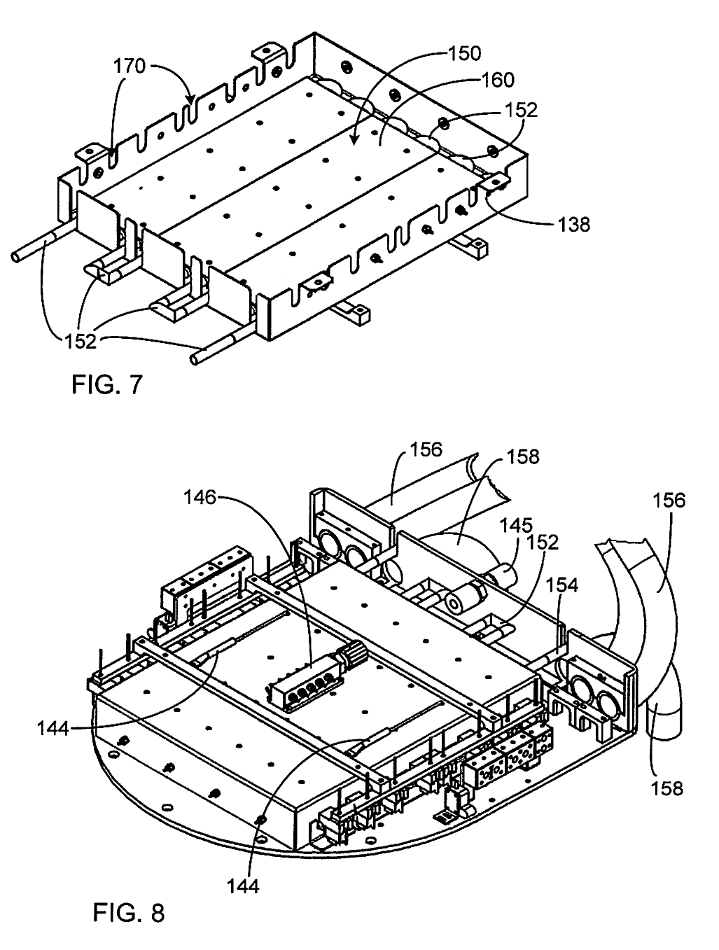

Referring to FIG. 6, the lamps 140 are generally uniformly spaced apart from each other in an array so as to generally uniformly span the entire surface area of window 148. Adapted for processing a 300 mm (12 inch) diameter wafer, eight single-element lamps 140 may be used. The lamps provide substantially uniform direct (line of sight) IR radiation through the window 148 onto the entire surface of wafer 70. The IR radiation energy impinging on the wafer surface preferably varies by less than 30, 20, 10 or 5% across the wafer surface. As shown in FIGS. 6 and 7, the lamps 140 may be placed in slots 170 in the lamp housing 138, to reduce heating of the end fittings on the lamps via adjacent lamps.

As shown in FIGS. 2, 6, 7 and 8, a cooling system 150 is provided on the IR assembly 126. The cooling system may include tubes 152 on or in the lamp housing 138. Liquid coolant is pumped through the tubes 152, at appropriate times, to cool the IR assembly 126. The liquid coolant is supplied to the tubes 152 through supply lines connecting to fittings 154, which may be on the housing cover 128 of the IR assembly 126. The tubes 152 may extend through heat sink plates 160 in the lamp housing 138. The cooling system 150 may also include an air manifold 146 and flow path through and/or around the lamp housing 138. Cooling air may be introduced through air inlet 145 for communication through a supply pipe (not shown) to be passed through and dispursed through air manifold 146 to move through the IR assembly 126, exiting through air exhaust line 158.

In use, the processor 20 is initially in the load/unload position as shown in FIG. 1. The upper chamber assembly 24 is raised up from the lower chamber assembly 22, allowing access to the plate assembly 80 from the side. A wafer 70 is placed onto the top plate 81, manually, or more typically by a robot. The wafer rests on the fingers 84. The lift actuators 92 then lower the upper chamber assembly 24 down onto the lower chamber assembly 22, forming the processing chamber 28 between them. The processor 20 is then in the process position shown in FIGS. 2 and 5. The bowl ring 96 may seal against the seal 40 to substantially seal the chamber 28. The chamber 28 may be exhausted (via a vacuum line), and it need not necessarily be air tight. Rather, the processor 20 may alternatively be designed so that vapors of the process chemicals used cannot readily escape into the surrounding environment.

With the processor in the process position, the lamps 140 are turned on and irradiate the wafer 70 through the window 148. The window 148 may be quartz, since quartz is substantially transparent to IR radiation, and it is also chemically inert and highly heat resistant. The generally uniform distribution of the lamps 140 across the spans of the window 148 result in a substantially uniform heat across the entire surface of wafer 70. The upper chamber body 102 and the top plate 81 may also be quartz, to better resist high processing temperatures resulting from exposure to the IR radiation. The shield plate 64 within the plate assembly 80 helps to block the IR radiation from penetrating into the lower chamber assembly 22. Exemplary shield plate 64 is quartz plate with a reflective coating. Components below the shield plate 64 generally may be conventional metal and plastic materials, and may otherwise be susceptible to heat deteriation.

Sulfuric acid, optionally along with hydrogen peroxide, are supplied into the chamber 28, simultaneously, or sequentially, or in alternating pulses. These process chemicals are generally supplied as liquids to the nozzles and then introduced into the chamber 28. Either or both process chemicals may be simultaneously delivered into the chamber 28 in the form of an atomized stream of small droplets from separate nozzles or ports in the process chamber 28. Atomizing, rather than spraying, helps to avoid localized temporary cooling of the wafer. This improves processing uniformity across the wafer. The motor 50 is activated to rotate the rotor assembly 26 and the wafer 70. Rotation speeds of 10-300 rpm may be used when the process chemicals are applied to the wafer 70. Rotation additionally adds to the uniformity of the IR radiation, and therefore the heat, on the surface of the wafer 70.

Combining hydrogen peroxide and sulfuric acid forms quasi-stable intermediate chemical species, which are believed to have high oxidation potential. Two of the more common of these species are H2SO5 (Caro's acid or peroxy monosulfuric acid) and H2S2O8 (peroxy disulfuric acid or PDSA). These species have a limited lifetime before they decompose, once again forming sulfuric acid. When separately supplied into the chamber 28, the hydrogen peroxide and the sulfuric acid react in a vapor cloud within the chamber in the area around the wafer 70, and therefore also directly on the wafer surface. This allows the highly oxidative quasi-stable chemical species formed by their interaction to immediately support oxidation of photoresist on the wafer surface, where they may contribute to the efficacy of the process before they start to decompose. The current process provides for the controlled dosing of amounts of hydrogen peroxide and sulfuric acid to the wafer surface so as to provide an effective supply of the highly effacious quasi-stable intermediates on the wafer surface.

The temperature of the wafer 70, or temperature of the process chemical liquid film on the wafer, may be monitored by temperature sensor 122. The wafer temperature may be controlled in a closed feedback loop via temperature sensor 122 and adjusting power to the lamps 140. This may be performed by an electronic controller or computer associated with the processor 20, or remotely located in the facility. The controller may also control other operations of the processor.

Process parameters may vary depending on the type of photoresist to be removed. As one example, the wafer 70 temperature is ramped up rapidly from room temperature to greater than 200, 250, 300, or 350° C., while delivering atomized sulfuric acid and hydrogen peroxide into the chamber 28 via atomized nozzles 112, and 114, respectively. The ramp up interval may be from about 5 to 30-45 seconds. After temperature ramp up, the temperature may be held steady at a dwell interval temperature for about 20 to 180 seconds, or longer. The wafer 70 may optionally be simultaneously rotated to provide more uniform heating and process chemical distribution. After the dwell interval, the wafer 70 may be rapidly cooled, to shorten processing time. Rapid cooling can be achieved via the cooling assembly 150, which primarily cools the IR lamps 140 and lamp housing 138. A fluid spray onto the wafer 70 primarily cools the wafer 70. Fluid spray may consist of DI water from nozzles 116. Some photoresists may be completely removed during the ramp up interval, making the dwell interval unnecessary.

After the photoresist removal, and as part of the rapid cooling, the wafer 70 may be rinsed with hot DI water, and then with ambient temperature DI water. This may optionally be followed by a cleaning step to remove sulfate residues or other materials, with the cleaning step performed in the same chamber 28, or in a different processing chamber.

Cooling water is pumped through the tubes 152 in the cooling assembly 150 when the lamp housing 138 exceeds a preset temperature, as detected by the lamp housing temperature sensors 144. Generally, cooling water moves through the tubes or coils 152 whenever the lamps 140 are on, and for a period of time after they are turned off. Clean dry air is similarly pumped or drawn through IR assembly 126 to provide additional cooling. The cooling assembly 150 blocks stray IR radiation from the IR assembly 126 and reduces or avoids heating up adjacent apparatus.

When processing is completed, the lift actuators 92 lift the upper chamber assembly 24 back up off of the lower chamber assembly 22. The processed wafer 70 may then be removed and a subsequent wafer loaded into the processor 20.

In contrast to conventional spray or wet bench processing using hydrogen peroxide and sulfuric acid, the processor 20 allows for processing at very high temperatures. Boiling of these process chemical solutions does not limit processing temperatures because they are not provided in bulk liquid form. The complications associated with pre-heating chemical solutions can also be avoided. Similarly, pumping and handling of high temperature chemical solutions is not required, which simplifies the facility design, and improves reliability.

Experimental results demonstrate that direct IR radiation is more effective than other forms of heating in removing photoresist. The IR radiation itself appears to affect the chemical bonding and cross-linking of the photoresist. Photoresist removal rates using direct IR are higher than in hot-plate testing, chemical heating, even in portions of the wafer that are shadowed from the IR radiation.

Atomizing the hydrogen peroxide and the sulfuric acid with on-wafer mixing and heating minimizes process chemical consumption. Testing as described in the examples below demonstrates that some photoresists may be completely removed using as little as 10 ml of chemical solutions on a 300 mm wafer. Since only small amounts of chemical solutions are needed, they can be used once, eliminating the need and problems associated with recycled chemistry. The amount of chemical solution needed may vary depending on the type of photoresist to be removed. In examples 1 and 8-11 below, the total volume of chemical solutions used is 45 ml. In contrast, known photoresist removal methods typically use about 1500 ml of chemical solution per 300 mm wafer. Similarly, examples 1 and 8-11 below use flow rates of 20 ml/minute of H2SO4 with 10 ml/minute of H2O2, whereas known photoresist removal methods typically use flow rates of about 500 ml/minute of both H2SO4 and H2O2 for a combined flow rate of about 1000 ml/minute.

Examples 2 and 6 demonstrate very low chemical solution consumption of 10 ml and 9 ml total, respectively. The methods accordingly may be run using very small amounts of chemical solutions. For example, in a process from removing photoresist on a 300 mm diameter wafer, the total chemical solution consumption (typically H2SO4 and H2O2) may be equal to or less than 500 ml, 250 ml, 100 ml, 50 ml, 30 ml, 15 ml or 10 ml. Correspondingly, in the present process, flow rates of H2SO4 may be equal to or less than 100, 50, 20, 10 or 5 ml/minute, generally with an H2O2 flow equal to about half of the H2SO4 flow rate. This results in combined flow rates in the present process of equal to or less than 150, 75, 30, 20 or 10 ml/minute. Proportionally more or less maximum amounts of chemical solutions (and flow rates) may similarly be used on wafers of other sizes having proportionally larger or smaller surface areas.

The processor 20 may be used to remove photoresist from substrates other than wafers. Accordingly, the term wafer as used here includes other substrates and workpieces as well.

### EXAMPLES WITH VARYING PARAMETERS

Testing was conducted with varying the following parameters: 1) temperature ramping; 2) maintained temperature (n degrees C., as measured by recording the temperature of the substrate; 3) exposure time in seconds; 4) the ratio of H2SO4 to H2O2; 5) the total volume of liquid chemical used in milliliters; and 6) wafer rotation measured in Revolutions Per Minute (“RPM's”).

Photo-resist removal may vary depending on the type of photo-resist, the implant dose, the implant energy, the implant species, and the thickness of photo-resist. The conditions described by the following examples were established by parameter optimization for a set of 1 um thick, 248 nm DUV resist implanted with BF2 at 30 KeV and at a dosage of 4E15 atoms/cm2, unless otherwise indicated.

### Example 1

General Process: A resist coated wafer was subjected to a chemical ratio of 2 (2 parts of H2SO4 to 1 part of H2O2) and exposed for 90 seconds. The substrate was rotatied below the IR lamps at 100 RPM. Lamp power was set to drive the wafer temperature from ambient to 250° C. in 20 seconds. This temperature was maintained for 70 seconds at which time the lamp power was cut off and the temperature was returned to near ambient with a DI rinse. All of the photo-resist was removed. The flowrate of H2O2 was 10 mL/min and the H2SO4 rate was 20 ml/min. Total usage was 45 ml of chemistry. Testing suggests that this method should be effective in removing 95% of highly implanted resist samples.

### Example 2

Low Volume Chemical Usage Process. A non implanted 1 um 248 DUV resist wafer was subjected to a chemical ratio of 2 and exposed for 20 seconds. The substrate was rotating below the IR lamps at 100 RPM. Lamp power was set to drive temperature from ambient to 250° C. in 20 seconds. The wafer temperature varied throughout this entire process from 25° C. up to 250° C. As soon as the temperature reached 250° C. the wafer was returned to near ambient with a DI rinse. All photo-resist was removed. The flowrate of H2O2 was 10 mL/min and the H2SO4 rate was 20 ml/min. Total usage was 10 ml of chemistry. This example demonstrates that certain types of resist can be fully removed with small chemical volumes.

### Example 3

No Hydrogen Peroxide Used: A resist wafer was subjected to an infinite chemical ratio and exposed for 90 seconds. The wafer was rotated below the IR lamps at 100 RPM. Lamp power was set to drive the wafer temperature from ambient to 250° C. in 20 seconds. This temperature was maintained for 70 seconds at which time the lamp power was cut off and the temperature was returned to near ambient with a DI rinse. The photo-resist was substantially removed. The flowrate of H2O2 was 0 mL/min and the H2SO4 rate was 20 ml/min. Total usage was 30 ml of chemistry. This example demonstrates that added peroxide enhances process performance, but that it is not required for all resist types.

### Example 4

Excess Peroxide Ratio: A resist wafer was subjected to a 0.1 chemical ratio and exposed for 90 seconds. The substrate was rotatied below the IR lamps at 100 RPM. Lamp power was set to drive the wafer temperature from ambient to 250° C. in 20 seconds. This temperature was maintained for 70 seconds at which time the lamp power was cut off and the temperature was returned to near ambient with a DI rinse. The photo-resist was partially removed. The flowrate of H2O2 was 20 mL/min and the H2SO4 rate was 2 ml/min. Total usage was 33 ml of chemistry. This example demonstrates a chemical mixture that has much more hydrogen peroxide than sulfuric acid is still able to remove photoresist but is not as efficient as higher sulfuric acid ratios. Subsequent observations show that low H2SO4 mixtures will boil below 250° C. Liquid to gas conversion of the chemistry may limit the effectiveness of this process.

### Example 5

High Total Chemical Volume: The wafer was subjected to a chemical ratio of 2 of and exposed for 100 seconds. The substrate was rotated below the IR lamps at 100 RPM. Lamp power was set to drive temperature from ambient to 250° C. which now required 30 seconds. This temperature was maintained for 70 seconds at which time the lamp power was cut off and the temperature was returned to near ambient with a DI rinse. All photo-resist was removed. The flowrate of H2O2 was 100 mL/min and the H2SO4 rate was 200 ml. Total usage was 500 ml of chemistry. This example shows that higher dispense rates and usage of chemical are feasible in terms of resist removal but require more energy to heat the chemistry and more energy to maintain a given set point in temperature.

### Example 6

Low Chemical Dispense Rate: A non implanted 1 um 248 DUV resist wafer was subjected to a chemical ratio of 2 of and exposed for 20 seconds. The substrate was rotated below the IR lamps at 100 RPM. Lamp power was set to drive temperature from ambient to 250° C. in 20 seconds. The wafer temperature varied throughout this entire process from 25° C. up to 250° C. As soon as the temperature reached 250° C. the wafer was returned to near ambient with a DI rinse. All photo-resist was substantially removed. The flowrate of H2O2 was 2 mL/min and the H2SO4 rate was 4 ml/min. Total usage was 9 ml of chemistry dispensed over 90 seconds. This examples shows that certain types of photoresist can be removed with low dispense volumes but less effectively than with using higher rates.

### Example 7

Extended Time: A 4 um thick, resist wafer implanted with BF2 at 40 KeV and at a dosage of 5E16 atoms/cm2 was subjected to a chemical ratio of 2 and exposed for 600 seconds. The substrate was rotated below the IR lamps at 100 RPM. Lamp power was set to drive the wafer temperature from ambient to 250° C. in 20 seconds. This temperature was maintained for 580 seconds at which time the lamp power was cut off and the temperature was returned to near ambient with a DI rinse. All photo-resist was removed. The flowrate of H2O2 was 10 mL/min and the H2SO4 rate was 20 ml/min. Total usage was 300 ml of chemistry. This example shows that even resist conditions that are extreme within the semiconductor industry can be removed with standard conditions at extended exposure times.

### Example 8

Higher Exposure Temperature: A resist wafer was subjected to a chemical ratio of 2 of and exposed for 90 seconds. The substrate was rotating below the IR lamps at 100 RPM. Lamp power was set to drive the wafer temperature from ambient to 350° C. in 60 seconds. This temperature was maintained for 30 seconds at which time the lamp power was cut off and the temperature was returned to near ambient with a DI rinse. All photo-resist was observed to be removed. The flowrate of H2O2 was 10 mL/min and the H2SO4 rate was 20 ml/min. Total usage was 45 ml of chemistry. This example demonstrates that higher temperatures can be used and result in complete resist removal.

### Example 9

Lower Maximum Temperature: A non implanted resist wafer was subjected to a chemical ratio of 2 and exposed for 90 seconds. The substrate was rotated below the IR lamps at 100 RPM. Lamp power was set to drive the wafer temperature from ambient to 100° C. in 20 seconds. This temperature was maintained for 70 seconds at which time the lamp power was cut off and the temperature was returned to near ambient with a DI rinse. All photo-resist was observed to be removed from the substrate. The flowrate of H2O2 was 10 mL/min and the H2SO4 rate was 20 ml/min. Total usage was 45 ml of chemistry. This example demonstrates that lower temperature processing can still result in complete photo-resist removal with some resist types.

### Example 10

Slower Temperature Ramp Rate: The resist wafer was subjected to a chemical ratio of 2 of and exposed for 90 seconds. The wafer was rotatied below the IR lamps at 100 RPM. Lamp power was set to raise the wafer temperature from ambient to 250° C. in 40 seconds. This temperature was maintained for 50 seconds at which time the lamp power was cut off and the temperature was returned to near ambient with a DI rinse. The photo-resist was substantially removed from the wafer. The flowrate of H2O2 was 10 mL/min and the H2SO4 rate was 20 ml/min. Total usage was 45 ml of chemistry. This example demonstrates that the ramp rate of the temperature may be a factor in photo-resist strip.

### Example 11

Zero RPM: The resist wafer was subjected to a chemical ratio of 2 of and exposed for 90 seconds. The substrate was stationery and not rotated below the IR lamps. Lamp power was set to increase the wafer temperature from ambient to 250° C. in 20 seconds. This temperature was maintained for 70 seconds at which time the lamp power was cut off and the temperature was returned to near ambient with a DI rinse. All photo-resist was removed. The flowrate of H2O2 was 10 mL/min and the H2SO4 rate was 20 ml/min. Total usage was 45 ml of chemistry. Even at zero RPM the wafer was completely stripped suggesting that RPM may not be a significant factor in resist removal.

### Example 12

500 RPM: The resist wafer was subjected to a chemical ratio of 2 of and exposed for 90 seconds. The substrate was rotatied below the lamps at 500 RPM. Lamp power was set to drive the wafer temperature from ambient to 250° C. in 20 seconds. This temperature was maintained for 70 seconds. Then the lamp power was cut off and the temperature was returned to near ambient with a DI rinse. All photo-resist was removed. The flowrate of H2O2 was 10 mL/min and the H2SO4 rate was 20 ml/min. Total usage was 45 ml of chemistry. At 500 RPM the wafer was completely stripped demonstrating that rpm may not be a significant factor in resist removal.

Thus, a novel processor has been shown and described. Various changes and substitutions may of course be made without departing from the spirit and scope of the invention. The invention therefore should not be limited, except by the following claims and their equivalents.

1. A processor comprising:
a processing chamber;
a fixture in the processing chamber for holding a wafer;
a plurality of nozzles in the processing chamber; and
an infrared radiating assembly including a plurality of infrared lamps outside of the processing chamber and positioned to radiate infrared light into the processing chamber and directly onto substantially an entire surface of a wafer on the fixture; and
a cooling assembly associated with the infrared radiating assembly.

2. The processor of claim 1 with the infrared lamps spaced apart from and generally parallel to each other.

3. (canceled)

4. The processor of claim 1 with the infrared lamps non-uniformly spaced apart.

5. The processor of claim 2 wherein the fixture is adapted to hold a wafer having a diameter less than a length of one or more of the infrared lamps.

6. The processor of claim 1 with the infrared lamps between the fixture and the cooling assembly.

7. (canceled)

8. The processor of claim 7 with the infrared lamps within a heater housing on a head plate, and with the cooling assembly on an outside surface of the heater housing.

9. The processor of claim 7 with the cooling assembly comprising chilled water tubes on the heater housing.

10. The processor of claim 7 with the heater housing including a cooling air flow manifold.

11. The processor of claim 1 further comprising an infrared blocking layer on the fixture.

12. (canceled)

13-18. (canceled)

19. A method for removing photoresist from a wafer, comprising:
placing the wafer on a fixture in a closed chamber;
irradiating and heating a surface of the wafer via infrared lamps in a heater assembly outside of the chamber, with infrared energy radiating through a window of the chamber directly onto the surface of the wafer;
contacting the wafer with sulfuric acid and hydrogen peroxide, with the sulfuric acid and hydrogen peroxide and infrared radiation reacting to remove photoresist from the surface of the wafer; and
actively cooling the heater assembly.

20. The method of claim 19 further comprising simultaneously providing an atomized mist of hydrogen peroxide and sulfuric acid into the chamber.

21. The method of claim 19 further comprising spinning the fixture.

22. The method of claim 19 wherein the wafer is a 300 mm diameter wafer and the total combined amount of hydrogen peroxide and sulfuric acid supplied is equal to or less 100 ml.

23. The method of claim 19 wherein the wafer is a 300 mm diameter wafer and the total amount of hydrogen peroxide and sulfuric acid supplied is equal to or less 50 ml.

24. The method of claim 19 wherein the wafer is a 300 mm diameter wafer and the combined flow rate of the hydrogen peroxide and the sulfuric acid together is 30 ml/minute or less.

25. A method for removing photoresist from a 12 inch diameter wafer, comprising:
placing the wafer on a fixture in a closed chamber;
irradiating a surface of the wafer via infrared radiation; and
applying no more than a combined volume 100 ml of hydrogen peroxide and sulfuric acid onto the wafer, with the hydrogen peroxide, sulfuric acid and infrared radiation reacting to remove photoresist from the surface of the wafer.

26. The method of claim 25 further comprising applying no more than a combined volume of 50 ml of hydrogen peroxide and sulfuric acid are used.

27. The method of claim 25 further comprising projecting infrared radiation through a window of the chamber directly onto the surface of the wafer.

28. The method of claim 25 wherein the photoresist is non-implanted and no more than a combined volume of 20 ml of hydrogen peroxide and sulfuric acid are used.
